(19) United States
(12) Patent Application Publication
(10) Pub. No.: US 2014/0310581 A1
(43) Pub. Date: Oct. 16, 2014

(54) METHOD FOR FORMING A CRC VALUE AND TRANSMITTING AND RECEIVING APPARATUS THEREFOR

(71) Applicant: Siemens Aktiengesellschaft, Munich (DE)

(72) Inventors: Jean Georgiades, Munich (DE); Markus Premke, Regensburg (DE); Bernhard Wiesgickl, Vilseck (DE)

(21) Appl. No.: 14/360,086

(22) PCT Filed: Dec. 13, 2012
(86) PCT No.: PCT/EP2012/075387

§ 371 Date: May 22, 2014

(30) Foreign Application Priority Data
Dec. 15, 2011 (DE) 10 2011 121 141.5

(51) Int. Cl. H03M 13/09; H04L 1/00

(52) U.S. Cl. CPC H03M 13/09; H04L 1/0061
USPC 714/807

(57) ABSTRACT

In a method for forming a CRC value using a plurality of data blocks, the CRC protection can be improved even further by virtue of the fact that, in order to form the CRC value, data blocks which are not transmitted to a receiver or have not been transmitted to a receiver are placed in front of data blocks which are transmitted to the receiver or have been transmitted to the receiver.

### PRIORITY STATEMENT

This application is the national phase under 35 U.S.C. §371 of PCT International Application No. PCT/EP2012/075387 which has an International filing date of Dec. 13, 2012, which designated the United States of America, and which claims priority to German patent application number DE 102011121141.5 filed Dec. 15, 2011, the entire contents of each of which are hereby incorporated herein by reference.

### FIELD

At least one embodiment of the invention generally relates to a method for forming a CRC value, a transmitting apparatus and a receiving apparatus.

### BACKGROUND

A common method for detecting errors in the context of data transmission or data storage, particularly for protecting the integrity of a message M during a transmission, resides in protecting the data by way of a cyclic redundancy check (CRC protection).

In the case of a message M having a length of r bits, the message is considered as a polynomial f(x) mod 2 having degree (n+r−1). The higher r x-powers of f(x) (i.e. from x^{(n+r-1)} to xⁿ) represent the message M, while the lower n x-powers of f(x) (i.e. from x⁽ⁿ⁻¹⁾ to x⁰) represent the CRC part. These n bits are determined such that the polynomial f(x) is a multiple of a previously determined polynomial g(x) mod 2 of the n-th degree. The polynomial g(x) is the generator polynomial of the (n,r) CRC code. The sender S of the message M transmits the polynomial f(x) to the receiver R. The receiver R receives a polynomial h(x), where h(x)=f(x) if the polynomial arrives without error. R performs an integrity test by dividing the received polynomial h(x) by the generator polynomial g(x) (division mod 2).

If the remainder after the division is unequal to zero, it is certain that errors occurred during the transmission. If the remainder after the division is equal to zero, it is highly probable that the message M arrived correctly, unless bit errors occurred with a certain residual-error probability at specific positions, whereby the received polynomial h(x) differs from f(x) yet the polynomial division mod 2 of h(x) by g(x) nonetheless returns a remainder of zero.

Depending on the magnitude of the numbers n and r and the representation of the polynomial g(x), there is a maximal number HD(n, r, g(x))=k, with the property that the polynomial division returns a remainder unequal to zero if up to k−1 errors occurred (conversely, this means that at least one combination of a number of k errors exists for which the polynomial division returns a remainder of zero). In coding theory, HD signifies the term “hamming distance”. The greater the HD, the lower the residual-error probability that, in the case of a residual result of “zero” after the polynomial division, an erroneous message has nonetheless arrived at the receiver.

Example: HD(8, 9, x⁸+x⁷+x⁶+x⁴+x²+x+1)=5.

This firstly means that a message M having a length of 9 bits is transformed into a polynomial f(x) mod 2 having degree 8+9−1=16 such that the leading 9 x-powers of f(x) represent the message M and the coefficients of the lower 8 x-powers are selected such that f(x) is a multiple of g(x)=x⁸+x⁷+x⁶+x⁴+x²+x+1. In this case, the value “HD( )=5” signifies that as a result of the polynomial division of the received polynomial h(x) by g(x), up to 5−1=4 errors can be detected with absolute certainty, and the division remainder will never be equal to zero in such a case.

The message M here includes different blocks A₁, A₂, . . . Aₖ and B₁, B₂, . . . Bₜ, the length of all “A” blocks totaling r_{A} bits and that of the “B” blocks totaling rB bits, where rA+r_{B}=r. However, only the “B” blocks and the CRC bits are transmitted to the receiver R, since the text of the “A” blocks should already be known to the receiver R. This means that both the “A” and the “B” blocks are taken into consideration by the sender S when determining the CRC bits, even though these “A” blocks are not ultimately transmitted to the receiver R.

The order of the blocks is not fixed, but is nonetheless known to both participants. It must also be taken into account in some cases that the maximal number of bits to be sent should not exceed an upper limit b_{MAX} (b_{MAX} could be e.g. 2 or 4 bytes). In order to achieve maximal integrity protection, a generator polynomial g(x) can therefore be used when forming the polynomial f(x) and/or when forming the CRC bits, wherein the following applies:

n+r_{B}<b_{MAX}+1 and

HD(n, r_{B}, g(x)) should be maximal.

After receiving the B blocks and the CRC bits, the receiver R uses this data and the already known “A” blocks to construct the polynomial h(x), and tests it by way of

### SUMMARY

At least one embodiment of the present invention is directed to further improving CRC protection.

At least one embodiment of the present invention is directed to a method. Advantageous embodiments of the method are the subject matter of the subclaims.

A method of at least one embodiment is for forming a CRC value using a plurality of data blocks, the method comprising:
forming the CRC value by placing data blocks, which are not or were not transmitted to a receiver, in front of data blocks which are or were transmitted to the receiver, wherein the data blocks which are not or were not transmitted to the receiver are not confidential information known only to the receiver and a sender.

### BRIEF DESCRIPTION OF THE DRAWINGS

A preferred but not in any way restrictive example embodiment of the invention will now be described in detail with reference to the drawings. In this situation the features are illustrated schematically and corresponding features are identified by the same reference characters. The figures show this in detail:

FIG. 1 shows a method according to at least one embodiment of the invention involving an interrelationship between a sender and receiver;

FIG. 2 shows an example embodiment of a block diagram of an example field bus communication system, in particular a field bus communication system according to the AS-Interface standard, for executing the method according to at least one embodiment of the invention as explained in connection with FIG. 1.

FIG. 3 shows, in a simplified and schematic illustration, an example embodiment of a master device and each of the slave devices each including a transmitting apparatus and a receiving apparatus.

FIG. 4 shows components of an example embodiment of the transmitting apparatus.

FIG. 5 shows components of an example embodiment of the receiving apparatus.

### DETAILED DESCRIPTION OF THE EXAMPLE EMBODIMENTS

A method of at least one embodiment is for forming a CRC value using a plurality of data blocks, the method comprising:
forming the CRC value by placing data blocks, which are not or were not transmitted to a receiver, in front of data blocks which are or were transmitted to the receiver, wherein the data blocks which are not or were not transmitted to the receiver are not confidential information known only to the receiver and a sender.

At least one embodiment of the invention is based on the finding that the order of the “A” and/or “B” blocks when forming the polynomial f(x) affects the quality of the protection.

On the sender side, using the method according to at least one embodiment of the invention for forming a CRC value, data blocks which are not transmitted to a receiver are placed in front of data blocks which are transmitted to the receiver.

On the receiver side, using the method according to at least one embodiment of the invention for forming a CRC value, data blocks which were not transmitted to the receiver are placed in front of data blocks which were transmitted to the receiver.

Assuming a polynomial f(x) having degree n+r−1=n+r_{A}+r_{B}−1, this means that the blocks are placed as follows:
The highest r_{A} x-powers of f(x) (i.e. from x^{n+r-1} to x^{n+r}_{B}) represent the “A” blocks, i.e. those blocks which are not or were not transmitted to the receiver since they should already be known to the receiver.
The next r_{B} x-powers of f(x) (i.e. from x^{n+r}_{B}⁻¹ to xⁿ) represent the “B” blocks, i.e. those blocks which are or were transmitted to the receiver.
The lowest n x-powers of f(x) (i.e. from xⁿ⁻¹ to x⁰) represent the CRC bits, which are also or were also transmitted to the receiver.

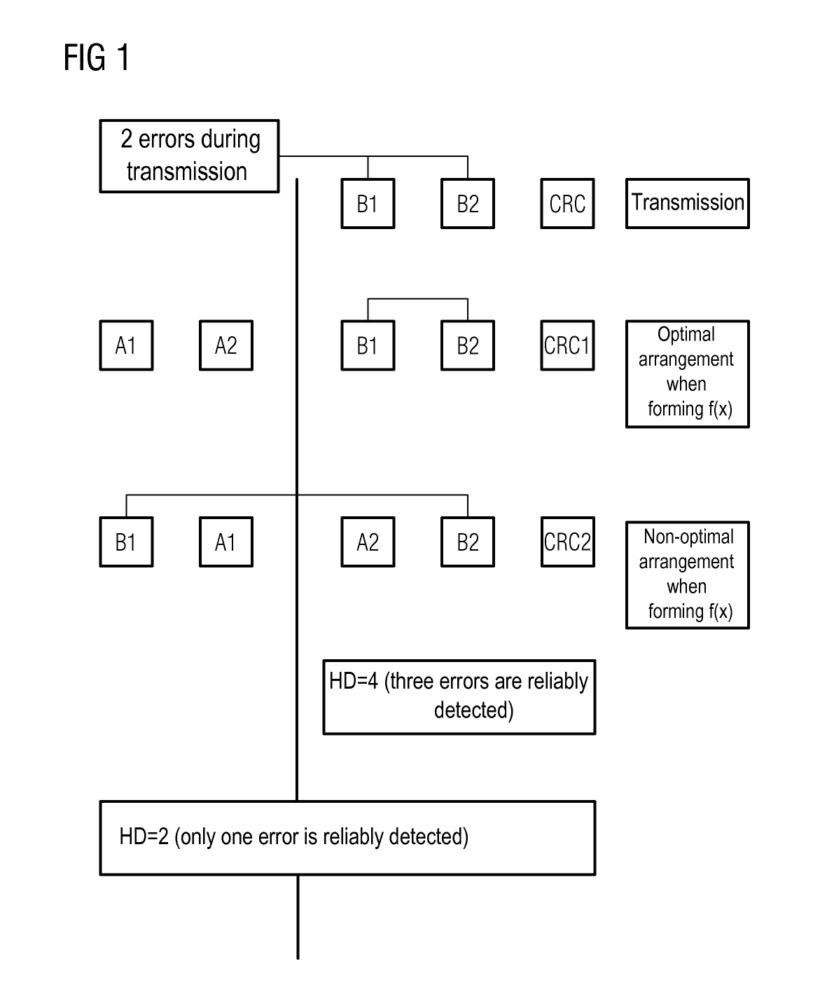

This interrelationship is explained below by way of example with reference to FIG. 1.

The message M includes the blocks A1, A2, B1 and B2. Provision is now made for forming the polynomial f(x) and determining the CRC bits. The value of the CRC block, which is influenced by all data blocks (“A” and “B”), also depends on the order of the data blocks when the polynomial f(x) is formed, resulting in the designations “CRC1” and “CRC2” in the figure. The blocks B1 and B2 with the corresponding CRC block are sent off to the receiver R (see first row in FIG. 1).

In the example according to FIG. 1, two errors occur during the transmission (see marked positions). If it is actually the case that the generator polynomial provides a 3-error guarantee (HD=4) for a message length of 2 data blocks+CRC block, but only a 1-error guarantee (HD=2) for a message length of 4 data blocks+CRC block, the following situation can arise:
If the arrangement of the data blocks was optimal during the formation of the polynomial f(x), these errors will be situated in the HD=4 range, and will therefore be detected (see second row in FIG. 1).
If the arrangement of the data blocks was not optimal during the formation of the polynomial f(x), these errors will be situated in the HD=2 range, meaning that they can remain undetected and a transmission received with errors may be accepted as correct due to the incorrect arrangement of the blocks (see third row in FIG. 1).

The optimal arrangement minimizes the actual real length of the message to be protected within the polynomial f(x) (i.e. the length between the most significant bit of the “B” blocks and the lowest bit of the CRC block). Any other arrangement will cause the distance between the most significant bit of the “B” blocks and the lowest bit of the CRC block to be increased unnecessarily, thereby potentially weakening the CRC protection, which would be expressed by a lower HD.

By virtue of the arrangement explained above, the “B” blocks (i.e. the blocks which are transmitted) enjoy maximal CRC protection. Their manner of placement means that the statement relating to HD applies, namely that up to HD−1 errors can be detected with absolute certainty. Any other placement of the “A” and “B” blocks would have resulted in at least parts of a “B” block being further than rB bits away from the CRC bit block and therefore the HD would certainly not have had a higher value (its value would very probably have been lower) and therefore the integrity protection likewise would not have been higher (it would very probably have been lower). The arrangement of the blocks as explained above therefore provides optimal protection.

In this way, at least one embodiment of the invention differs from a previously known approach, which resides in “deleting” the “A” blocks during coding by means of so-called “punctured codes”. By contrast, the “A” blocks are included in the formation of f(x) according to the present invention.

The data blocks which are not to be or were not transmitted to the receiver may represent e.g. one or more bus address(es) and/or one or more device identifier(s) of the receiver of the data.

The data blocks which are to be or were transmitted to the receiver may represent payload data and/or one or more sequential number(s).

A particularly advantageous use of at least one embodiment of the method relates to field bus communication, in particular field bus communication as per the AS-Interface standard.

The AS-Interface (ASi: actuator sensor interface) is a standard for field bus communication and was developed for the connection of actuators and sensors. Its objective is to replace parallel cabling. The AS-Interface is primarily used at sensor/actuator level in this case. The AS-Interface became an international standard in 1999 and is specified in EN 50295 and IEC 62026-2.

A transmitting apparatus as per at least one embodiment of the invention for data and/or messages is so designed as to form a CRC value using at least one embodiment of the method explained above.

A receiving apparatus as per at least one embodiment of the invention for data and/or messages is likewise so designed as to form a CRC value using the method explained above.

A master device as per at least one embodiment of the invention for field bus communication, in particular for field bus communication according to the AS-Interface standard, comprises such a transmitting apparatus.

A slave device as per at least one embodiment of the invention for field bus communication, in particular for field bus communication according to the AS-Interface standard, comprises such a receiving apparatus.

In the case of bidirectional data transmission between master device and slave device, the master device can also have a receiving apparatus according to at least one embodiment of the invention and conversely the slave device can also have a transmitting apparatus according to at least one embodiment of the invention.

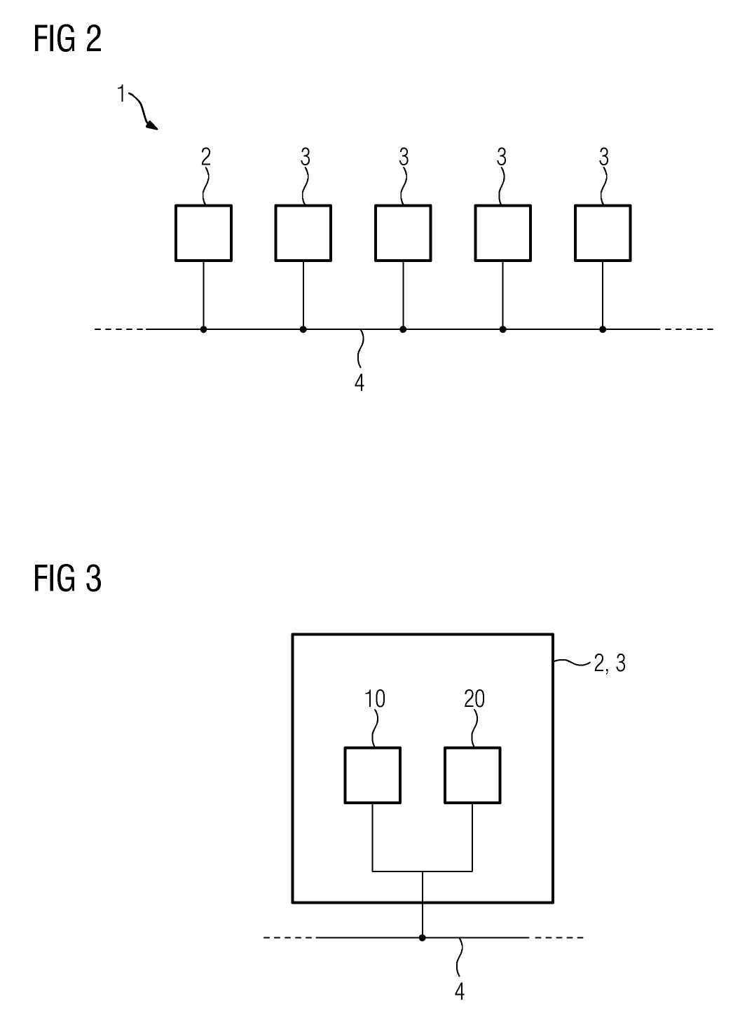

The invention and further advantageous embodiments of the invention as per features in the subclaims are explained in greater detail below with reference to example embodiments in FIGS. 2 to 4.

In a simplified and schematic illustration, FIG. 2 shows a block diagram of an example field bus communication system 1, in particular a field bus communication system according to the AS-Interface standard, for executing the method according to at least one embodiment of the invention as explained in connection with FIG. 1. However, transmission links may take the form of any desired network, e.g. Ethernet, or any other wire-based transmission links or networks, or also wireless transmission links or networks, e.g. WLAN.

In this case, the communication system 1 comprises a master device 2 (often simply referred to as “master”) and a plurality of slave devices 3 (often likewise simply referred to as “slaves”), which are connected to each other via a field bus 4. The field bus 4 allows bidirectional data transmission from the master device 2 to the slave devices 3 and conversely from the slave devices 3 to the master device 2.

The master device 2 controls the logical operation and timing of the field bus 4. The slave devices 3 are addressed cyclically via their bus address by the master device 2, and only generate a reply to the master device when they are addressed by the master device. The slave devices 3 are integrated into sensors or actuators, for example.

As shown in detail in FIG. 3 in a simplified and schematic illustration, both the master device 2 and each of the slave devices 3 has a transmitting apparatus 10 and a receiving apparatus 20 in each case. The transmitting apparatus 10 and the receiving apparatus 20 can also be combined in a single combined transmitting/receiving apparatus.

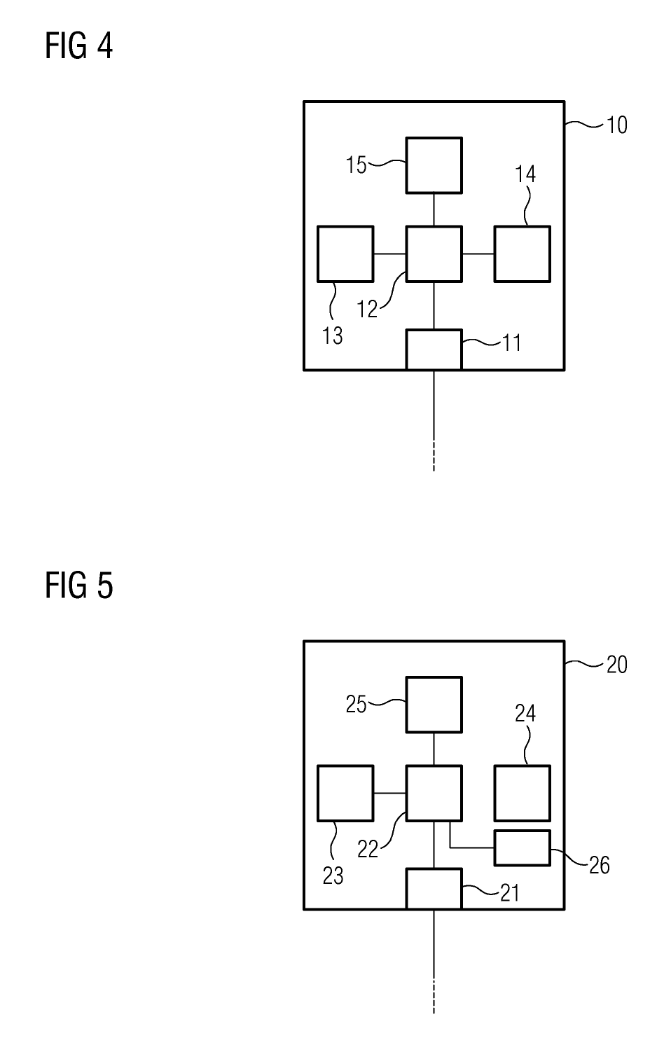

As shown in FIG. 4, the transmitting apparatus 10 comprises a transmit unit 11, a calculation unit 12, a memory 13 for payload data which is to be transmitted (“B blocks”), a memory 14 for data which is not to be transmitted (“A blocks”) and is already known to the receiver, and at least one shift register 15 with suitable feedback paths.

Using the at least one shift register 15, the calculation unit 12 forms a CRC value from the data stored in the memories 14 and 15, wherein for the purpose of forming the CRC value the data blocks A, which are not transmitted to a receiving apparatus 20, are placed in front of the data blocks B, which are transmitted to a receiving apparatus 20. The calculation unit 12 then joins the blocks B and the generated CRC value together to form a message M and passes this to the transmit unit 11, which converts it into corresponding analog electrical signals and feeds these into the field bus 4.

As shown in FIG. 5, the receiving apparatus 20 comprises a receive unit 21, a calculation and analysis unit 22, a memory 23 for received payload data (“B blocks”), a memory 24 for data which has not been transmitted (“A blocks”) and is known to the receiver, at least one shift register 25 and a memory 26 for a received CRC value.

A message M which is received via the field bus 4 in the form of analog electrical signals is converted into digital signals by the receive unit 21 and forwarded to the calculation and analysis unit 22. The latter breaks the message M down into the B blocks and the CRC value. The B blocks are stored in the memory 23 and the CRC value in the memory 26. Using the at least one shift register 15, the calculation and analysis unit 22 then forms a CRC value from the A blocks stored in the memory 24 and the B blocks stored in the memory 23, wherein for the purpose of forming the CRC value the data blocks A, which were not received by the receiving apparatus 20, are placed in front of the data blocks B, which were received by the receiving apparatus 20. The calculation and analysis unit 22 then compares the CRC value which was received as part of the message M and stored in the memory 26 with the calculated CRC value and, in the event of a discrepancy, an error in the data transmission via the field bus 4 is inferred. The message M may be e.g. discarded in this case.

1. A method for forming a CRC value using a plurality of data blocks, the method comprising:
forming the kCRC value by placing data blocks, which are not or were not transmitted to a receiver, in front of data blocks which are or were transmitted to the receiver, wherein the data blocks which are not or were not transmitted to the receiver are not confidential information known only to the receiver and a sender.

2. The method of claim 1, wherein a message M of the length r bits is considered as a polynomial f(x) having degree n+r−1=n+r_{A}+r_{B}−1, where r_{A} is the length in bits of the data blocks which are not to be or were not transmitted to the receiver and r_{b} is the length in bits of the data blocks which are to be or were transmitted to the receiver, and wherein
the relatively highest r_{A} x-powers of f(x) (i.e. from x^{n+r-1} to x^{n+r}_{B}) represent the data blocks which are not to be or were not transmitted to the receiver,
the next r_{B} x-powers of f(x) (i.e. from x^{n+r}_{B}⁻¹ to xⁿ) represent the data blocks which are to be or were transmitted to the receiver, and
the relatively lowest n x-powers of f(x) (i.e. from xⁿ⁻¹ to x⁰) represent the CRC bits, which are also or were also transmitted to the receiver.

3. The method of claim 1, wherein the data blocks which are not to be transmitted to the receiver represent at least one of one or more bus addresses and one or more device identifiers.

4. The method of claim 1, wherein the data blocks which are to be transmitted to the receiver represent at least one of payload data and one or more sequential numbers.

5. A method, comprising:
using the method of claim 1 for field bus communication.

6. A transmitting apparatus, designed to form a CRC value using the method of claim 1.

7. A receiving apparatus, designed as to form a CRC value using the method of claim 1.

8. A master device for field bus communication, comprising:
the transmitting apparatus of claim 6.

9. A slave device for field bus communication, comprising:
the receiving apparatus of claim 7.

10. A method, comprising:
using the method of claim 1 for improving the CRC protection.

11. A method for forming a CRC value using a plurality of data blocks, comprising:
forming the CRC value by placing data blocks, which are not or were not transmitted to a receiver, in front of data blocks which are or were transmitted to the receiver, wherein the data blocks which are not to be transmitted to the receiver represent at least one of one or more bus addresses and one or more device identifiers.

12. The method of claim 2, wherein the data blocks which are not to be transmitted to the receiver represent at least one of one or more bus addresses and one or more device identifiers.

13. The method of claim 2, wherein the data blocks which are to be transmitted to the receiver represent at least one of payload data and one or more sequential numbers.

14. The method of claim 3, wherein the data blocks which are to be transmitted to the receiver represent at least one of payload data and one or more sequential numbers.

15. A method, comprising:
using the method of claim 1 for field bus communication according to the AS-Interface standard.

16. The master device of claim 8, wherein the master device is for field bus communication according to the AS-Interface standard.

17. A master device for field bus communication, comprising:
a transmitting apparatus, designed to form a CRC value using the method of claim 1; and
a receiving apparatus, designed as to form a CRC value using the method of claim 1.

18. The slave device of claim 9, wherein the slave device is for field bus communication according to the AS-Interface standard.

19. A slave device for field bus communication, comprising:
a transmitting apparatus, designed to form a CRC value using the method of claim 1; and
a receiving apparatus, designed as to form a CRC value using the method of claim 1.
